(19) United States
(12) Patent Application Publication
(10) Pub. No.: US 2009/0142170 A1
(43) Pub. Date: Jun. 4, 2009

(54) Loadport

(75) Inventor: Mitsuo Natsume, Aichi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: Shinko Electric., Ltd., Tokyo (JP)

(21) Appl. No.: 12/292,407

(22) Filed: Nov. 19, 2008

(30) Foreign Application Priority Data
Nov. 29, 2007 (JP) 2007-309350

(51) Int. Cl. H01L 21/677

(52) U.S. Cl. 414/222.07

(57) ABSTRACT

A load port particularly well-suited to application in batch processing semiconductor manufacturing processes is provided with a load port main body having a main table onto which a FOUP containing wafers is placed, a mapping means for mapping the wafers contained within the FOUP, and the like, and is further provided with a displacing means for moving the FOUP placed on the main table between the main table and a predetermined position removed a distance from the load port main body, in which the displacing mechanism is provided with an open space enabling the passing of a FOUP which contains wafers between the aforementioned predetermined position and a piece of equipment located adjacent to the load port main body.

### FIELD OF THE INVENTION

The present invention relates to a load port for use in a minienvironment employed in a semiconductor manufacturing process.

### BACKGROUND ART

In the course of manufacturing semiconductors, wafer processing is carried out in a clean room in order to improve the yield and quality. However, recent advancements in circuitry miniaturization and higher concentrations of integrated elements, as well as increases in wafer size, and the like, has made it difficult to realize, both in terms of technology and cost, clean room environments that are capable of controlling fine dust and other microcontaminant airborne particulates. Therefore, instead of improving on the clean room, a smaller self-contained clean space called a “minienvironment” has recently been widely adopted as a localized space for enclosing wafers and the peripheral areas around the wafers during conveyance and process treatment steps. When a minienvironment is employed, two important devices are utilized: a FOUP (Front-Opening Unified Pod), which is a wafer storing container that is used to hold wafers during a semiconductor manufacturing process; and a load port that serves both as a port of entry and exit for wafers between the FOUP and the semiconductor processing equipment, and as a portion for interfacing with the transport mechanism for loading and unloading the FOUP from the semiconductor processing equipment. That is to say, clean room construction and operating costs are controlled by maintaining a high-degree clean environment within the FOUP and semiconductor processing equipment, and a low-degree clean environment between the load port and an exterior environment.

The main role normally performed by a load port is that of acting as an intermediary between the FOUP and a wafer loading and unloading device disposed within the semiconductor processing equipment by being brought into close contact with the door on the FOUP so as to be caused to open and close (see, for example, Patent Publication Reference No. 1); and it is therefore sometimes referred to as a “FOUP opener”; however, there are also load ports under development that are provided with a function for mapping the number, position, and the like, of wafers contained within the FOUP (see, for example, Patent Publication Reference No. 2).

Patent Publication Reference No. 1: Japanese Patent Publication 2004-140011

Patent Publication Reference No. 2: Japanese Patent Publication 2006-173510

### SUMMARY OF THE INVENTION

In the past, wafers were unloaded one at a time from the FOUP and loaded into the semiconductor processing equipment through the load port for processing in the semiconductor processing equipment one at a time; developments in recent years, however, have seen multiple wafers unloaded from the FOUP at once and loaded into the semiconductor processing equipment together for processing as a group in the semiconductor processing equipment, so-called batch processing semiconductor manufacturing. In the case of batch processing such as that described above, a FOUP storage cabinet called a stocker is provided within the clean room in the space outside of the semiconductor processing equipment, a plurality of FOUP are stored in the stocker, wafers are unloaded sequentially from the FOUP through the load port disposed within the stocker into the semiconductor processing equipment for processing, after which the processed wafers are gathered and returned to their original FOUP through the load port, whereby the process is completed. When batch processing such as that described above is performed, an identification number is assigned to each FOUP, each wafer within each FOUP is mapped for easy management, with the aim of further increasing efficiency and reducing costs.

The present invention has been developed based on a consideration of the above-described problems, and the idea that a mapping function can be provided to the load port for mapping the wafers contained within the FOUP. In particular, it is a main object of the present invention to provide a load port that is capable of efficiently facilitating the transfer of FOUP contained within a stocker within a clean room between the stocker and the exterior of the stocker in a batch processing semiconductor manufacturing process.

That is to say, the load port according to the present invention is a load port for use in a semiconductor manufacturing process, comprising a load port main body provided with a main table onto which FOUP which contain wafers are to be placed, and a means for mapping wafers contained in the FOUP; further comprising a displacing mechanism for moving a FOUP that has been placed on the main table between said main table a predetermined position removed a distance from load port main body, wherein the displacing mechanism is provided with adequate open space facilitating the passing of FOUP which contain wafers between the aforementioned predetermined position and another piece of semiconductor manufacturing adjacent to the load port main body.

Here, the FOUP, as described above, refers to a storage container called a “Front-opening Unified Pod” (FOUP) for enclosing and conveying wafers in a clean environment. The load port main body refers to a device that functions as an interface portion between a piece of semiconductor processing equipment and the outside of the semiconductor processing equipment, regardless of whether the load port main body acts in a direct or indirect manner, in a clean room used in a semiconductor manufacturing process. A mapping means provided to a load port main body such as that described above can be, for example, a means provided with a device for detecting, remembering, and so on, the position of each wafer, the total number of wafers contained (including whether or not any wafers are contained), and the like. Normally, a FOUP houses a multi-level cassette for containing a plurality of wafers, and the mapping device maps and remembers the number of wafers contained on each level of the cassette (including whether or not there are wafers present), the position of each wafer, and so on. That is to say, the “predetermined position removed a distance from the load port main body” refers to a position above the main table, to the side the main table, at a diagonal to the main table; just as the phrase states, a position that is that is not the position where the load port main body is located. In other words, the predetermined position refers to a position separated by a distance between said position and the load port main body, excluding positions that are contiguous the load port main body or on the interior of the load port main body. Furthermore, as for the aforementioned open space provided to the displacing mechanism, the aforementioned displacing mechanism may adopt a configuration in which the structural members of the displacing mechanism are provided with a gap for facilitating passage of a FOUP between the structural members, or alternatively, a configuration in which the displacing mechanism is provided with an open space that facilitates passage of the FOUP by circumventing the structural members of the displacing mechanism, or a configuration in which the displacing mechanism has an open space from which structural members of the displacing mechanism present have been excluded.

A load port according to the present invention of a configuration such as that described above may operate in a manner so as to: first, load a FOUP that has been conveyed thereto by a convenient conveyance means onto the main table, where the mapping means can carry out mapping of the wafers contained in the FOUP; and next, use the displacement means to move the FOUP to a predetermined position at a distance removed from the load port main body, and transfer the FOUP along with the wafers contained therein through the aforementioned open space to another, adjacent piece of semiconductor processing equipment. Further, the load port main body can receive transfer of the FOUP containing wafers from the aforementioned adjacent other piece of semiconductor processing equipment at the aforementioned predetermined position through the aforementioned open space, return the FOUP to the top of the main table with the displacement means, and have the FOUP transported to a different position with a convenient conveyance means.

For example, a stocker capable of holding a plurality of FOUP can be arranged adjacent to a piece of semiconductor processing equipment capable of batch processing as the aforementioned other piece of semiconductor processing equipment, and if we assume that the stocker is provided with the load port according to the present invention, by use of the load port according to the present invention it becomes possible to directly load and unload FOUP containing wafers that have been mapped by the mapping means, and FOUP containing wafers that have undergone the complete semiconductor processing and been converted into semiconductors (and which, of course, have been subjected to the mapping process beforehand). Note that the transfer of wafers between the stocker and the semiconductor processing equipment can be performed by an appropriate load port (even a conventional load port differing from that according to the present invention) in a hermetically sealed state. That is to say, the environment within the stocker can be maintained at a lower level of cleanliness in comparison to the environment within the semiconductor processing equipment, and the wafers can be transferred to and from the stocker by the load port according to the present invention while remaining contained within the FOUP. Moreover, because wafers contained in a FOUP held within the stocker can be subjected to mapping process in advance by the load port according to the present invention, it becomes possible to shorten the length of time required to carry out a batch processing semiconductor manufacturing process, and to reduce costs, in an efficient manner. Accordingly, the load port according to the present invention can be said to be a load port that is appropriate for application in a batch processing semiconductor manufacturing process employing a minienvironment.

Further, with conventional load ports, it is often the case that two specialized load ports are arranged adjacently next to a piece of semiconductor processing equipment, with one load port used for removing wafers from a FOUP positioned thereon and passing them into the semiconductor processing equipment, and the other load port for receiving processed wafers from the semiconductor processing equipment and returning the processed wafers to the empty FOUP positioned thereon. Considering such conditions in a semiconductor manufacturing process, it can be ascertained that even in the case of batch processing, if two specialized load ports, one for removing wafers from the FOUP and the other for returning wafers to FOUP, respectively, are arranged for use adjacently on the outside of the stocker (on the side opposite that of the semiconductor processing equipment) as load ports according to the present invention, it will be difficult to provide a wide enough open space on either side of either load port. Here, as the load port according to the present invention is provided with a displacing mechanism, if the predetermined position with respect to the main table is set as a position located above the main table, because FOUP can be moved in an up and a down direction by the displacing mechanism so as to enable the loading and unloading of FOUP from a stocker positioned above the load port main body, space can be used more efficiently.

Still further, by providing the displacing mechanism, including a displacing mechanism such as the case of the above-described raising and lowering mechanism, with an auxiliary table on which FOUP are to be loaded at a position removed a distance from the load port main body, including the aforementioned predetermined remote position, it becomes possible to stably move FOUP even to a position located at a distance removed from the main table.

In particular, if the displacing mechanism is provided with an auxiliary table such as that described above, in order to ensure that the main table and auxiliary table do not interfere with each other, it is desirable that the auxiliary table be provided with a depression portion so as to avoid interfering with the main table when FOUP are loaded onto the main table. In this way, it becomes unnecessary to modify the structure of the main table of already existing load ports, or at the least to reduce the need for such modification.

According to the load port of the present invention, because it becomes possible to directly load and unload FOUP which contain wafers that have been subjected to a mapping process from a piece of equipment used in a semiconductor manufacturing process, such as a stocker disposed adjacent to another piece of semiconductor processing equipment for use in a batch processing semiconductor manufacturing process, that is located adjacent to a position removed a distance from the load port main body, it is not necessary to subject wafers to a mapping process when the wafers are extracted and inserted from a piece of semiconductor processing equipment such as the stocker, and the environment within the stocker and the like can be maintained in a relatively low degree of cleanliness in comparison to that of semiconductor processing equipment; whereby, beneficial effects such as reduction in the time and costs of the semiconductor manufacturing process can be efficiently achieved. Therefore, according to the present invention, it is possible to provide a load port that is extremely well suited for advantageous application in batch processing semiconductor manufacturing processes.

### DESCRIPTION OF THE PREFERRED EMBODIMENTS

Hereinafter a preferred embodiment of the present invention will be described with reference to the drawings. FIG. 1 is a side view of a section of a clean room A used in a semiconductor manufacturing process in which a load port 1 according to the current embodiment of the present invention is employed. FIG. 2 is a top view of the same clean room A shown in FIG. 1. As shown in each of the aforementioned drawings, the clean room A contains a piece of semiconductor processing equipment B and a stocker C, which are disposed in close contact in relation to each other, and two units of a load port 1 according to the current embodiment are arranged adjacently on the side of the stocker C opposite that of the semiconductor processing equipment B. The load port 1 on one side is a load port for use when a FOUP 4, which is a container holding wafers (not shown), is to be loaded into the stocker C through a shutter Ca provided on the stocker C; the load port 1 on the other side is for use when a FOUP 4 containing wafers that have been subjected to the semiconductor process that is stored in the stocker C is to be unloaded from the stocker C. The construction of the above-described two load port 1 units is the same. Further, the stocker C stores a plurality of FOUP 4 concurrently, from which wafers are removed in sequence in each of cassettes 41 (shown by the double-dotted lines), and two units of a conventional load port 10 are used for returning each of the cassettes 41 which contain wafers that have been subjected to the semiconductor process and thereby been converted into semiconductors to each of the FOUP 4, said conventional load ports 10 being disposed in close proximity to the semiconductor processing equipment B. Still further, as to the FOUP 4 used in the above described process, an appropriate prior art FOUP may be used. Further still, with respect to the semiconductor processing equipment B and the stocker C, appropriate batch processing compatible semiconductor processing equipment and stocker may be used therefor. Note that the environments within the semiconductor processing equipment B and the FOUP 4 are maintained in a state of high cleanliness; however, the environments within the stocker C and the entirety of the clean room A are maintained in a comparatively lower degree of cleanliness. Hereinafter, the construction of the load port 1 according to the current embodiment of the present invention will be described.

As shown in FIGS. 3 and 4, the load port 1 according to the current embodiment if formed mainly from a load port main body 2, and a raising and lowering mechanism 3, which is a type of a displacing mechanism for moving a FOUP 4 which is placed onto the load port main table 27. The load port main body 2 is of the same construction as that of a typical conventional load port 10, comprising a substantially vertically disposed load port frame 21 in the shape of a rectangular panel, a support plate 22 disposed in a substantially horizontal orientation and slightly inclining from a position midway up the height of the load port frame 21 at which it is mounted by members such as a bracket 23 and the like, and a mapping device 22 disposed at a position on the rear face, or the like, of the load port frame 21 (illustrated in FIGS. 1 and 2). The load port frame 21 can be maintained in a standing posture by mounting a chassis 25 to the bottom portion thereof, and also enables the load port frame 21 to be moved around within the clean room A, where the load port frame 21 is usually positioned such that the rear face thereof is in close contact with the stocker C. Note that although the load port frame 21 is shown in FIGS. 3 and 4 so that it is possible to discern the interior portion of the load port main body 2, which is enclosed by the support plate 22 and chassis 25, the interior area is normally covered by a cover 28 (shown by the double dotted line).

Further, as shown in FIGS. 3, 4, 5, and 6, an openable and closable door 26 is formed on the load port frame 2 at the upper section of the support plate 22, said door 26 causing a door (not shown) provided on the rear face of the FOUP 4 to be opened when in the state in which it has been brought into close contact with the door 26, said door 26 also normally being capable of communicably connecting the FOUP 4 and the adjacent semiconductor processing equipment B and blocking outside air from entering said FOUP 4 and said adjacent semiconductor processing equipment B; however, the current embodiment does not employ the door 26. Still further, a main table 27, directly onto which FOUP 4 that are carried by a conveyance device or the like are placed, is provided directly above the support plate 22. The main table 27 shown in the drawings is formed from a panel member that forms a substantially triangular planar shape, on which are formed three protruding portions 27a on the upper face thereof and protruding upward therefrom, and by causing the protruding portions 27a to couple with the holes formed on the bottom of the FOUP 4 (not shown), the position of a FOUP 4 that is placed on the main table 27 can be set. The main table 27 may further be provided with a function for moving a FOUP 4 that has been placed thereon toward and away from the door 26, a function for changing the orientation direction of a FOUP 4 that has been placed thereon by a conveyance device or the like at an arbitrary orientation so that the FOUP 4 is oriented in the correct direction; however, such functions are not used in the current embodiment. Further, the mapping means for subjecting the wafers contained within each FOUP 4 to a mapping process may be formed of the above-described mapping means 24, a raising and lowering device (not shown) for setting the position of the mapping means 24 mainly with respect to the longitudinal (vertical) direction thereof, and the like. Here, when the wafer mapping process is performed, a lid (not shown) disposed on the rear face of the FOUP 4 is temporarily opened. In order not to reduce the degree of cleanliness of the environment within the FOUP 4 at that time, the load port main body 2 is provided with an airtight structure for facilitating the saturation of the interior thereof with an N₂ purge gas, and by carrying out the mapping process in the state in which the airtight structure and the FOUP 4 with lid open are connected, the environment within the FOUP 4 can be maintained in a high degree of cleanliness.

The raising and lowering mechanism 3 is provided with a auxiliary table onto which FOUP 4 may be placed instead of on the main table 27 of the load port main body 2, and the auxiliary table 31 is provided with a raising and lowering mechanism 32, which is a type of displacing mechanism for raising and lowering the auxiliary table 31 between a lowered position of the raising and lowering mechanism mounted near the main table 27 and a predetermined position set at a position higher than the upper end of the load port main frame 21, and a guide 33 for stabilizing the operation of the raising and lowering mechanism 32. The auxiliary table 31 overlaps the upper face of the support plate 22 when the support plate 22 is in the lowered position shown in FIGS. 3 and 5, and is formed from a member having a substantially panel shape forming a depression portion 31a that does not interfere with the main table 27 in the lowered position and the above-described operation of the main table 27. The auxiliary table 31 is provided with three protruding portions 31b which protrude upwards from the upper surface of the auxiliary table 31 at positions differing from the positions of the protruding portions 27a of the main table 27, and by causing the protruding portions 31b to couple with different holes (not shown) formed on the bottom of the FOUP 4 from the above-described holes, the position of a FOUP 4 that has been placed on the auxiliary table 31b can be set. That is to say, on the bottle of the FOUP 4 there are holes formed for fixing the position of the FOUP 4, three among said holes for coupling with the protruding portions 27a of the main table 27 and the remaining three of said holes for coupling with the protruding portions 31b of the auxiliary table 31.

The raising and lowering device 32 according to the current embodiment is formed from a plurality (two are shown in the drawings) of hydraulic cylinders or gas pressure cylinders 320. More specifically, each of the cylinders 320 is provided with a cylindrical main body 321 interposed in a vertical orientation between the carriage 25 of the load port main body 2 and the support plate 22, and a rod 322 protruding upward from the cylinder main body 321 and passing through the support plate 22 the upper end thereof being fixed in place at the auxiliary table 31. The cylinder main body 321 also functions as a support member for supporting the support plate 22 of the load port main body 2. Further, by extending upward or retracting downward the cylinder main body 321 by applying or releasing hydraulic pressure or gas pressure to the rod 322, the auxiliary table 31 may be moved up and down between the lowered position (FIGS. 3 and 5), in which it overlaps the support place 22, and the predetermined raised position (FIGS. 4 and 6). Note that the predetermined raised position refers to the forward position (the position directly in front of) of the shutter Ca provided on the stocker C for loading FOUP 4 into the stocker C or extracting FOUP 4 from the stocker C. Further, the guide portion 33 is formed from a plurality of guide poles 331 (three are shown in the drawings) passing through the support plate 22 vertically the upper end thereof being fixed in place on the auxiliary table 31, and guide rings 332 for slidably supporting each of said guide poles 331 in the respective position thereof passing through the support plate 22. That is to say, in accordance with the raising and lowering of the auxiliary table 31 by the raising and lowering device 32, the guide poles 331 operating in line with the guide rings 332 moving up and down serve to improve the stability of the movement of the auxiliary table 31 onto which FOUP 4 has been placed by two cylinders 320.

Further, in the raised position shown in FIGS. 4 and 6, in order to facilitate the smooth loading and unloading of the FOUP 4 through the shutter Ca of the stocker C, a space 34 in which no structural members comprising the raising and lowering device 3 are present is provided from the rear of a FOUP 4 that has been placed on the auxiliary table 31 to the front of the shutter Ca of the stocker C. That is, FOUP 4 can be passed between the load port 1 and the stocker C through the obstacle free space 34. There are, of course, no structural members of the load port main body 2 present between the FOUP 4 and stocker C at the raised position.

Further, the loading and unloading of FOUP 4 from the stocker C is performed according to a procedure such as that described below.

First, the wafers contained in a FOUP 4 that has been placed on the main table 27 of the load port main body 2 by the conveying device in the preceding step are subjected to a mapping process by the mapping means while the FOUP 4 is maintained in an airtight state such as that described above. Next, once a FOUP 4 that has been placed on the auxiliary table 31 by the raising and lowering device is raised up to the raised position (refer to the imaginary lines in FIGS. 1 and 2), the shutter Ca automatically opens and a transfer device Cb is extended from the stacker C; the transfer device Cb raises the FOUP 4 from the auxiliary table 31, releasing the coupling between the protrusion portions 31b and the holes on the bottom of the FOUP 4, and carries the FOUP 4 into the stocker C. The plurality of FOUP 4 contained within the stocker C are loaded onto the load port 10 in order, and the wafers, which are contained in cassettes held within the FOUP 4, are transported in the state of being contained in the cassettes and maintained in an airtight state to the semiconductor processing equipment B. Note that because wafers extracted from a FOUP 4 have already been subjected to a mapping process by the load port 1, the load port 10 within the stocker C does not necessarily need to be provided with a mapping means, enabling costs to be reduced. Further, empty FOUP 4 are automatically relocated by a convenient means onto the load port 10 provided alongside for use in unloading. On the other hand, wafers that have completed processing and been converted into semiconductors by the semiconductor processing equipment B are inserted into the FOUP 4 in the state of being contained in the cassettes 41 maintained in an airtight state by the above-described load port 10 for unloading housed within the stocker C. When the doors of the FOUP 4 close, said FOUP 4 are automatically carried in order by the transfer device Cb to the interior of the stocker C, and when the shutter Ca opens, the FOUP 4 are moved to the auxiliary table 31, which has been in standby at the raised position at the neighboring load port 1 of the load port 1. Continuing, once the auxiliary table 31 and FOUP 4 have been lowered to the lowered position through the operation of the raising and lowering device 3, the FOUP 4 are placed onto the main table 27, and then carried by the conveying device to the next processing station.

As described above, without loss or degradation of any of the functionality provided by conventional load ports, if the load port 1 according to the current embodiment of the present invention is employed, it becomes possible to move a FOUP 4, which has placed temporarily on the main table 27 and then transferred to the auxiliary table 31 by the raising and lowering device (a displacing mechanism) and subsequently moved while on the auxiliary table 31, to a position removed a distance from the load port main body 2, to carry the wafers contained in each FOUP 4, which have already been subjected to a mapping process, to the adjacent stocker C, and to unload FOUP 4 containing wafers that have completed processing and been converted to semiconductors from the stocker C as is; therefore, it is possible to greatly improve operational efficiency and reduce costs in a batch processing semiconductor manufacturing process that employs a minienvironment.

Note that the present invention is not limited to the above-described preferred embodiments. For example, the displacing mechanism is not limited to being a raising and lowering device 3 such as that of the above-described embodiment, but can be a displacing mechanism for moving FOUP on the auxiliary table 31 to the right and left, or diagonal direction. In addition, the actual parts used to form each portion of the load port main body, displacing mechanism, and the like, are not limited to being those use in the above-described embodiment; so far as the gist of the present invention is not deviated from or transgressed, a wide range of variations is possible.

### BRIEF DESCRIPTION OF THE DRAWINGS

FIG. 1 is a side view of a portion of a clean room in which the load port according to the current embodiment of the present invention is employed.

FIG. 2 is a plan view of the floor plan of the same portion of the clean room shown in FIG. 1.

FIG. 3 is a perspective view of the auxiliary table of the load port when in the lowered position.

FIG. 4 is a perspective view of the auxiliary table of the same load port when in the raised position.

FIG. 5 is an enlarged perspective view of a portion of the auxiliary table of the same load port when in the lowered position.

FIG. 6 is an enlarged perspective view of a portion of the auxiliary table of the same load port when in the raised position.

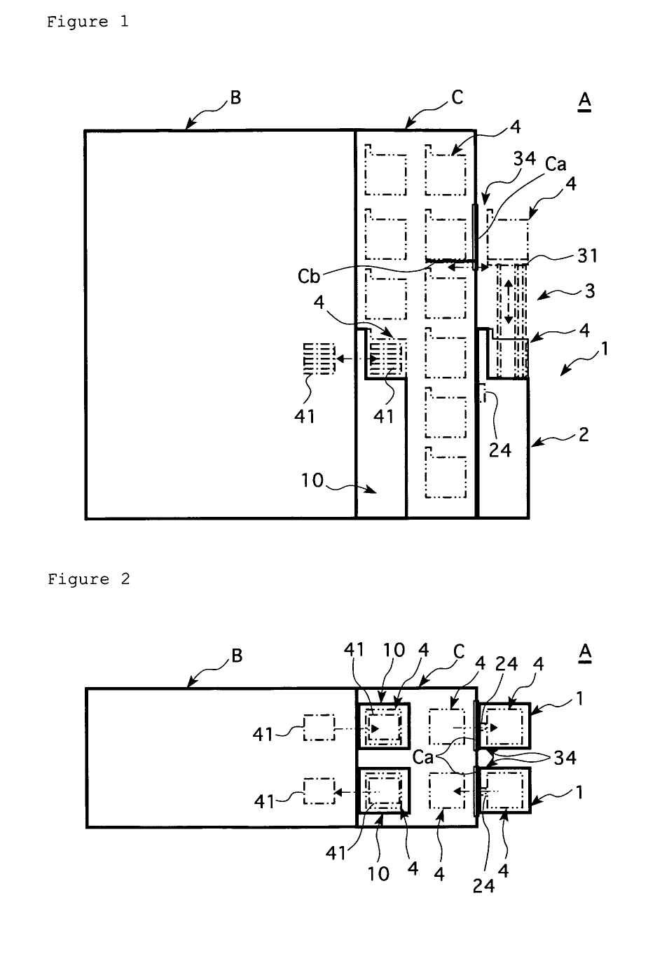

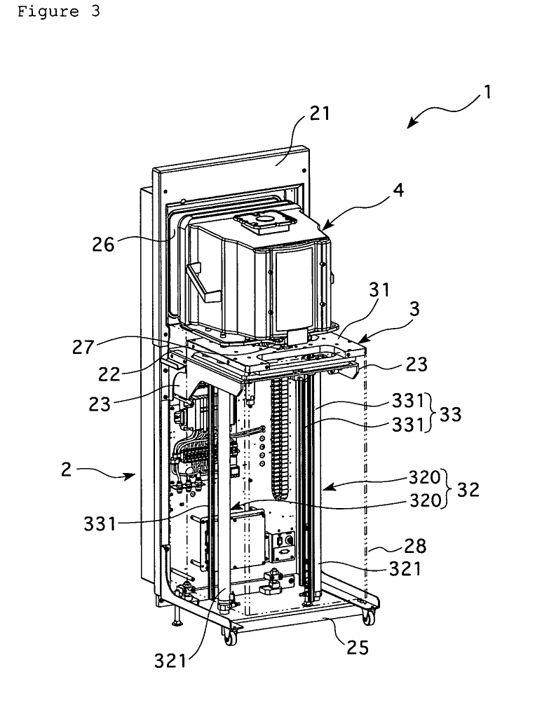

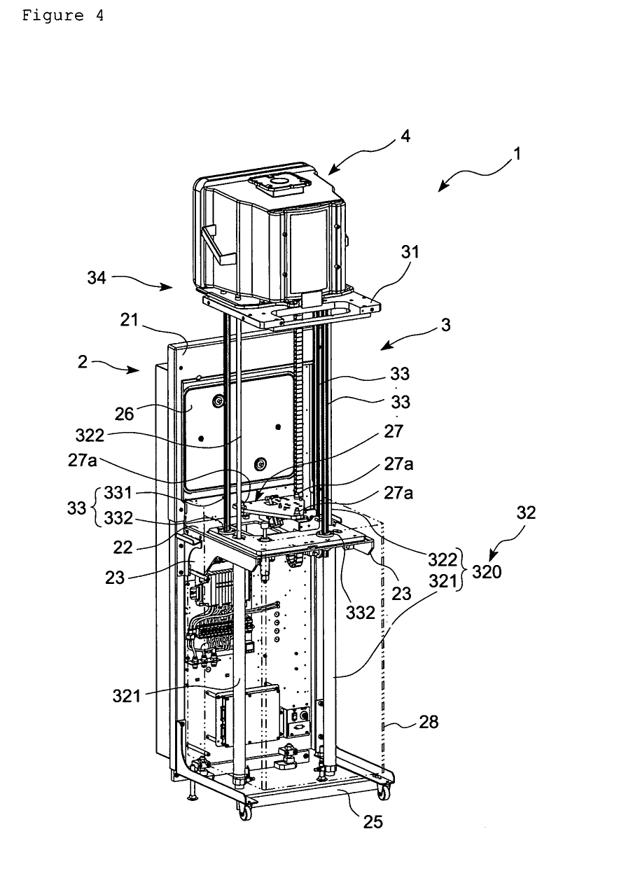

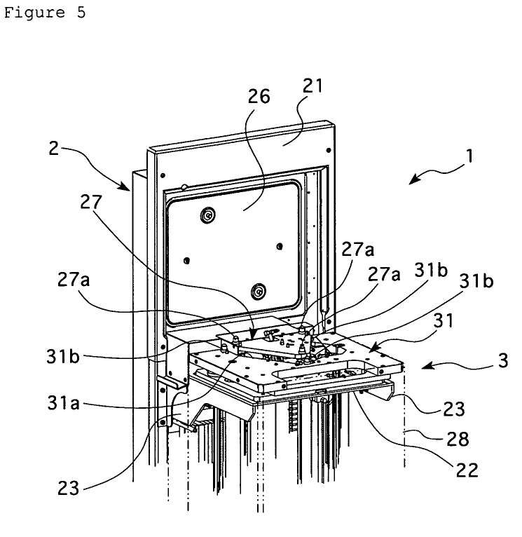

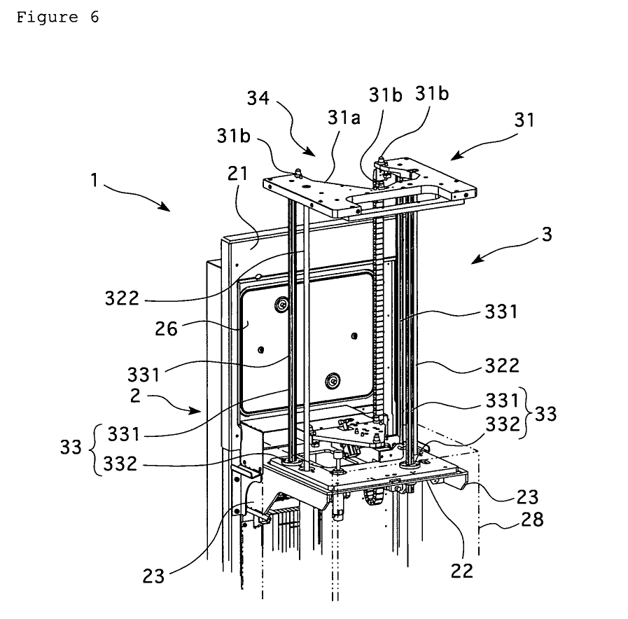

### TERMINOLOGY

Load port 1

Load port main body 2

Displacing mechanism 3 (raising and lowering device)

FOUP 4

Mapping means 24

Main table 27

Auxiliary table 31

Depression portion 31a

Raising and lowering device 31

Open space 34

Clean room A

Semiconductor processing equipment B

Stocker C

1. A load port for use in a semiconductor manufacturing process, comprising a load port main body provided with a main table for accommodating the loading thereon of a FOUP which contain wafers, and a means for mapping the wafers contained in the FOUP; further comprising a displacing mechanism for moving the FOUP between the main table and a predetermined position removed a distance from the load port main body, wherein said displacement mechanism is provided with an open space for enabling the passing of the FOUP which contain wafers between the predetermined position and another piece of semiconductor processing equipment located adjacent to the load port main body.

2. A load port according to claim 1, wherein the displacing mechanism is a raising and lowering mechanism for raising and lowering the FOUP between the main table and a position above said main table that has been specified as the predetermined position.

3. A load port according to claim 1, wherein the displacing mechanism is provided with an auxiliary table onto which the FOUP are to be placed at positions removed a distance from the load port main body and including the predetermined position.

4. A load port according to claim 3, wherein a depression portion for avoiding interference with the main table when the FOUP is placed on said main table is formed on the auxiliary table.

5. A load port according to claim 2, wherein the displacing mechanism is provided with an auxiliary table onto which the FOUP are to be placed at positions removed a distance from the load port main body and including the predetermined position.
